(19) United States
(12) Patent Application Publication
(10) Pub. No.: US 2025/0044696 A1
(43) Pub. Date: Feb. 6, 2025

(54) COMPOSITION FOR REMOVING EDGE BEAD FROM METAL CONTAINING RESISTS, DEVELOPER COMPOSITION OF METAL CONTAINING RESISTS, AND METHOD OF FORMING PATTERNS USING THE COMPOSITION

(71) Applicant: SAMSUNG SDI CO., LTD., Yongin-si (KR)

(72) Inventors: Taeho KIM, Suwon-si (KR); Minsoo KIM, Suwon-si (KR); Hyungrang MOON, Uiwang-si (KR); Si-Kyun PARK, Suwon-si (KR); Jin-Hee BAE, Suwon-si (KR); Seung HAN, Suwon-si (KR); Jongpil HO, Suwon-si (KR); Gyeong Ryeong BAK, Suwon-si (KR); Myoungsoo SONG, Suwon-si (KR); Gyeonghun PARK, Suwon-si (KR)

(21) Appl. No.: 18/784,565

(22) Filed: Jul. 25, 2024

(30) Foreign Application Priority Data
Aug. 4, 2023 (KR) 10-2023-0102399

(51) Int. Cl. G03F 7/11; G03F 7/004; G03F 7/16

(52) U.S. Cl. CPC G03F 7/11; G03F 7/0042; G03F 7/161; G03F 7/168

(57) ABSTRACT

A composition for removing edge beads from metal-containing resists, a developer composition of metal-containing resists, and methods of forming patterns using the same are disclosed. The composition according to one or more embodiments includes a C1 to C10 carboxylic acid compound substituted with at least one fluorine; and an organic solvent.

### CROSS-REFERENCE TO RELATED APPLICATION

The present application claims priority to and the benefit of Korean Patent Application No. 10-2023-0102399, filed in the Korean Intellectual Property Office on Aug. 4, 2023, the entire content of which is incorporated herein by reference.

### BACKGROUND

### 1. Field

This disclosure relates to compositions for removing edge beads from metal-containing resists, developer compositions of metal-containing resists, and methods of forming patterns using the same.

### 2. Description of the Related Art

In recent years, the semiconductor industry has seen a substantially continuous reduction of critical dimensions, and this dimensional reduction necessitates the development of new types (kinds) of high-performance photoresist materials and a patterning method that can meet the demand or desire for processing and patterning with increasingly smaller features.

In addition, with the recent rapid development of the semiconductor industry, a semiconductor device is desired or required to have a fast operation speed and large storage capacity, and in line with this requirement, process technology for improving integration, reliability, and a response speed of the semiconductor device is being developed or pursued. For example, it is important or desirable to accurately control/implant impurities in working regions of a silicon substrate and to interconnect these regions to form a device and/or an ultra-high-density integrated circuit. The ultra-high-density integrated circuit may be achieved or realized by a photolithographic process. For example, it is important or desirable to integrate the photolithographic process including coating a photoresist on the substrate, selectively exposing it to ultraviolet (UV) (including extreme ultraviolet (EUV)), electron beams, X rays, and/or the like, and then, developing it.

For example, in the process of forming the photoresist layer, while rotating the silicon substrate, the resist is mainly coated on (e.g., top surface of) the substrate, but the resist may also be coated on an edge and rear surface of the substrate, which may cause pattern defects in the subsequent semiconductor processes such as etching an/or ion implantation processes. Accordingly, a process of stripping and removing the photoresist coated on the edge and rear surface of the silicon substrate by using a thinner composition, that is, an edge bead removal (EBR) process is performed. The EBR process requires or desires a composition that exhibits excellent or suitable solubility for the photoresist and that can effectively removes beads and the photoresist remaining in the substrate and generates no resist residue.

There thus is a need or desire to develop a photoresist that can ensure excellent or suitable etch resistance and resolution in the photolithography process, while improving sensitivity and critical dimension (CD) uniformity, and can improve line edge roughness (LER) characteristics, and a developer composition that can implement these needed or desired features.

### SUMMARY

Aspects according to one or more embodiments are directed toward a composition for removing edge beads from metal-containing resists and/or toward a developer composition of metal-containing resists.

Aspects according to one or more embodiments are directed toward a method of forming patterns using the composition.

Additional aspects will be set forth in part in the description which follows and, in part, will be apparent from the description, or may be learned by practice of the presented embodiments of the disclosure.

According to one or more embodiments, a composition according to one or more embodiments includes a C1 to C10 carboxylic acid compound substituted with at least one fluorine; and an organic solvent. The composition is for removing an edge bead from a metal-containing photoresist and/or is a developer composition of a metal-containing photoresist.

According to one or more embodiments, a method of forming patterns according to one or more embodiments includes coating a metal-containing photoresist composition on a substrate, coating the aforementioned composition for removing edge beads from metal-containing resists along an edge of the substrate, drying and heating to form a metal-containing photoresist layer on the substrate, exposing the metal-containing photoresist layer to light, and developing the metal-containing photoresist layer.

According to one or more embodiments, a method of forming patterns according to one or more embodiments includes coating a metal-containing photoresist composition on a substrate, removing metal-containing resist edge beads, drying and heating to form a metal-containing photoresist layer on the substrate, exposing the metal-containing photoresist layer to light, and developing the metal-containing photoresist layer using the aforementioned developer compositions of metal-containing resists.

According to one or more embodiments, a method of forming patterns according to one or more embodiments includes coating a metal-containing photoresist composition on a substrate; coating the aforementioned composition for removing edge beads from metal-containing resists along an edge of the substrate, drying and heating to form a metal-containing photoresist layer on the substrate, exposing the metal-containing photoresist layer to light; and developing the metal-containing photoresist layer using the aforementioned developer compositions of metal-containing resists.

The composition for removing edge beads from the metal-containing resists according to one or more embodiments reduces the metal-based contamination inherent (e.g., reduces the inherent metal-based contamination present) in the metal-containing resists and removes the resist coated on the edge and the rear surface of the substrate, thereby satisfying requirements of processing and patterning of smaller features.

The developer composition of metal-containing resists according to one or more embodiments may implement excellent or suitable contrast characteristics, excellent or suitable sensitivity, and reduced line edge roughness (LER) by minimizing or reducing defects present in the metal-containing photoresist layer after the exposure process and facilitating development.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic view of a photoresist coating apparatus.

FIGS. 2 to 4 are cross-sectional views schematically showing the process sequence of a method of forming patterns according to one or more embodiments of the present disclosure.

FIG. 5 is a contrast curve obtained by measuring the thickness of each exposed region on the patterned wafer.

### DETAILED DESCRIPTION

Hereinafter, embodiments of present disclosure are described in more detail with reference to the accompanying drawings. In the following description of the present disclosure, the well-known functions or constructions will not be described in order to clarify the present disclosure.

In order to clearly illustrate the present disclosure, certain descriptions and relationships that should be understood by those of ordinary skill in the art are not provided, and throughout the disclosure, the same or similar configuration elements are designated by the same reference numerals. Also, because the size and thickness of each configuration shown in the drawings are arbitrarily shown for better understanding and ease of description, the present disclosure is not necessarily limited thereto.

In the drawings, the thickness of layers, films, panels, regions, and/or the like, may be exaggerated for clarity. In the drawings, the thickness of a part of layers, regions, and/or the like, may be exaggerated for clarity. It will be understood that if (e.g., when) an element such as a layer, film, region, or substrate is referred to as being “on” another element, it can be directly on the other element or intervening elements may also be present.

In the present disclosure, the term “substituted” refers to replacement of a hydrogen atom by deuterium, a halogen, a hydroxyl group, a thiol group, a cyano group, a carbonyl group, an amino group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a C1 to C20 sulfide group. As used herein, the term “unsubstituted” refers to that a hydrogen atom remains as a hydrogen atom without being replaced by another substituent.

In the present disclosure, the term “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a “C1 to C5 alkyl group” refers to that the alkyl chain contains 1 to 5 carbon atoms, and may be selected from among methyl, ethyl, propyl, iso-propyl, n-butyl, iso-butyl, sec-butyl, and t-butyl.

Non-limiting examples of the alkyl group include a methyl group, an ethyl group, a propyl group, an isopropyl group, a butyl group, an isobutyl group, a tert-butyl group, a pentyl group, a hexyl group, and/or the like.

In the chemical formulas described herein, “t-Bu” represents a tert-butyl group.

In the present disclosure, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

In the present disclosure, if (e.g., when) a definition is not otherwise provided, the term “heterocycloalkyl group” refers to a cycloalkyl group including at least one hetero atom selected from among N, O, S, P, and Si.

In the present disclosure, if (e.g., when) a definition is not otherwise provided, the term “alkenyl group” refers to a linear or branched aliphatic hydrocarbon group, and may refer to an aliphatic unsaturated alkenyl group containing one or more double bonds.

In the present disclosure, if (e.g., when) a definition is not otherwise provided, the term “alkynyl group” refers to a linear or branched aliphatic hydrocarbon group, and may refer to an unsaturated alkynyl group containing one or more triple bonds.

In the present disclosure, the term “aryl group” refers to a substituent in which all elements of a cyclic substituent have p-orbitals, and these p-orbitals form a conjugate and may include monocyclic, polycyclic or fused ring (i.e., rings that share adjacent pairs of carbon atoms) functional groups.

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

For example, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, and/or a (e.g., any suitable) combination thereof, but the present disclosure is not limited thereto.

For example, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, a substituted or unsubstituted benzonaphthofuranyl group, a substituted or unsubstituted benzonaphthothiophenyl group, a substituted or unsubstituted benzofuranofluorenyl group, a substituted or unsubstituted benzothiophenefluorenyl group, and/or a (e.g., any suitable) combination thereof, but the present disclosure is not limited thereto.

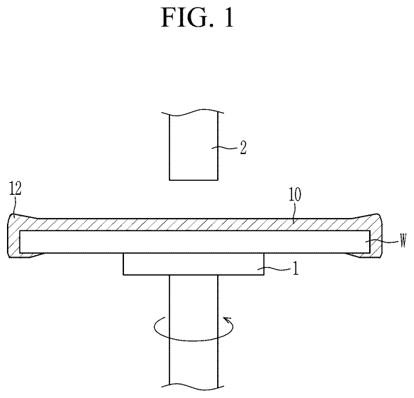

FIG. 1 is a schematic view showing the photoresist coating apparatus.

Referring to FIG. 1, a substrate support portion 1 on which a substrate W is placed is equipped within the photoresist coating apparatus, and the substrate support portion 1 includes a spin chuck or a spin coater.

The substrate support portion 1 rotates in a first direction at a set or predetermined rotation speed to provide a centrifugal force to the substrate W. A spray nozzle 2 may be positioned over (or on) the substrate support portion 1 but located off the upper portion of the substrate W in the atmospheric region (e.g., the spray nozzle 2 may be spaced apart from the upper surface of the substrate W) so that the spray nozzle may be moved toward the upper portion of the substrate W and spray a photoresist solution 10 in the spraying (e.g., act or task) step. Accordingly, the photoresist solution 10 is coated on the surface of the substrate W by the centrifugal force. Herein, while the photoresist solution 10 supplied to the center of the substrate W is coated by spreading to the edge of the substrate W by the centrifugal force, a portion of the photoresist solution 10 moves to the side surfaces of the substrate W and the lower surface of the edge of the substrate W.

For example, in the coating process, the photoresist solution 10 is coated (e.g., mainly) by a spin coating method, in which a set or predetermined amount of the photoresist solution 10 with (e.g., a suitable) viscosity is supplied to the center portion of the substrate W and gradually spreads toward the edge of the substrate W by the centrifugal force.

Accordingly, the photoresist is evenly formed through a rotational movement (e.g., speed) of the substrate support portion.

This rotation also evaporates a solvent from the solution (e.g., the photoresist solution 10) and thereby the viscosity thereof is gradually increased, resulting in a portion (e.g., a relatively large amount) of the photoresist accumulated on the edge of the substrate by the action of surface tension and some even onto the lower surface of the edge of the substrate W, which is referred to as edge beads 12.

Hereinafter, a composition for removing edge beads from metal-containing resists and/or a developer composition of metal-containing resists according to one or more embodiments is described.

The composition for removing edge beads from metal-containing resists (e.g., metal-containing photoresists) and/or the developer composition of metal-containing resists (e.g., metal-containing photoresists) according to one or more embodiments includes a C1 to C10 carboxylic acid compound substituted with at least one fluorine; and an organic solvent.

The C1 to C10 carboxylic acid compound substituted with at least one fluorine can promote a reaction with the photoresist in the exposed region, thereby further increasing a difference in solubility between the exposed region and the non-exposed region.

In addition, by including fluorine, which is an electron withdrawing group, an appropriate or suitable pKa for improving sensitivity and resolution can be maintained, which is advantageous or desirable for realizing fine patterns and controlling scum.

In some embodiments, the C1 to C10 carboxylic acid compound substituted with at least one fluorine may be represented by Chemical Formula 1.

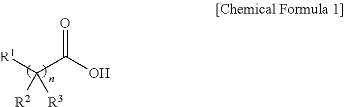

In Chemical Formula 1,
R¹ to R³ may each independently be hydrogen, fluorine, a fluorine-containing group, or a substituted or unsubstituted C1 to C5 alkyl group,
n may be an integer of 1 to 5, and
at least one of R¹ to R³ may be fluorine or a fluorine-containing group.

For example, at least one of R² or R³ may be fluorine or a fluorine-containing group.

For example, R² and R³ may each independently be fluorine or a fluorine-containing group.

For example, R² and R³ may each independently be fluorine.

As an example, the C1 to C10 carboxylic acid compound substituted with at least one fluorine may be at least one of difluoroacetic acid, 2,2-difluoropropionic acid, trifluoroacetic acid, or monofluoroacetic acid.

In one or more embodiments, the composition for removing edge beads from metal containing resist and/or the developer composition of metal-containing resists may include about 0.01 to about 5 wt % of the aforementioned C1 to C10 carboxylic acid compound substituted with at least one fluorine, and about 95 to about 99.99 wt % of the organic solvent.

In one or more embodiments, the composition for removing edge beads from metal containing resist and/or the developer composition of metal-containing resists may include the aforementioned C1 to C10 carboxylic acid compound substituted with at least one fluorine in an amount of about 0.05 to about 5 wt %, for example, about 0.05 to about 1 wt %, or about 0.05 to about 0.5 wt %.

The organic solvent included in the composition for removing edge beads from metal-containing resists and/or the developer composition according to one or more embodiments may include propylene glycol methyl ether (PGME), propylene glycol methyl ether acetate (PGMEA), propylene glycol butyl ether (PGBE), ethylene glycol methyl ether, diethylglycolethylmethylether, dipropylglycoldimethylether, ethanol, 2-butoxyethanol, n-propanol, isopropanol, n-butanol, isobutanol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methylethylketone, methylisobutylketone, tetrahydrofuran, dimethylsulfoxide, dimethyl formamide, acetonitrile, diacetone alcohol, 3,3-dimethyl-2-butanone, N-methyl-2-pyrrolidone, dimethyl acetamide, methyl-2-hydroxy-2-methylpropanate (HBM), gamma butyrolactone (GBL), 1-butanol, ethyl lactate (EL), diene butyl ether (DBE), diisopropyl ether (DIAE), acetyl acetone, 4-methyl-2-pentanol (or methyl isobutyl carbinol (MIBC)), 1-methoxy-2-propanol, 1-ethoxy-2-propanol, toluene, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methyl propionate, ethyl 3-ethoxy propionate, methyl 3-ethoxy propionate, methyl pyruvate, ethyl pyruvate, butyl acetate, butyl lactate, methyl-2-hydroxyisobutyrate, methoxybenzene, n-butyl acetate, 1-methoxy-2-propyl acetate, methoxyethoxy propionate, ethoxyethoxy propionate, and/or a (e.g., any suitable) mixture (e.g., combination) thereof, but the present disclosure is not limited thereto.

The composition for removing edge beads from metal-containing resists (e.g., metal-containing photoresists) according to one or more embodiments of the present disclosure may be effective (e.g., particularly effective) in removing metal-containing resists, for example, undesirable metal residues, such as tin-based metal residues.

In addition, the developer composition of metal-containing resists (e.g., metal-containing photoresists) according to one or more embodiments of the present disclosure reduces or minimizes defects present in the metal-containing photoresist layer after the exposure process and allows for easy development, thereby realizing excellent or suitable pattern characteristics.

In addition, excellent or suitable sensitivity and reduced line edge roughness (LER) can be achieved.

In some embodiments, one or more other additives (to be described in more detail later) may be included, and the organic solvent may be included in a balance amount excluding the other included components.

The one or more other additives may be selected from among a surfactant, a dispersant, a moisture absorbent, and a coupling agent.

In one or more embodiments, the surfactant may be a sulfuric acid ester salt, a sulfonic acid salt, a phosphoric acid ester, a soap, an amine salt, a quaternary ammonium salt, a polyethylene glycol, an alkylphenol ethylene oxide adduct, a polyhydric alcohol, a nitrogen-containing vinyl polymer, and/or a (e.g., any suitable) combination thereof, but the present disclosure is not limited thereto. For example, the surfactant may include an alkylbenzenesulfonate salt, an alkylpyridinium salt, polyethylene glycol, or a quaternary ammonium salt.

In one or more embodiments, the dispersant may be an epoxy resin, polyvinyl alcohol, polyvinyl butyral, polyvinylpyrrolidone, glucose, sodium dodecyl sulfate, sodium citrate, oleic acid, linoleic acid, and/or a (e.g., any suitable) combination thereof but the present disclosure is not limited thereto.

For example, the moisture absorbent may serve to prevent or reduce the metal included in the photoresist composition from being oxidized by moisture. In one or more embodiments, the moisture absorbent may be polyoxyethylene nonylphenolether, polyethylene glycol, polypropylene glycol, polyacrylamide, and/or a (e.g., any suitable) combination thereof, but the present disclosure is not limited thereto.

In one or more embodiments, the coupling agent may include a silane coupling agent. The silane coupling agent may be vinyltrimethoxysilane, vinyltriethoxysilane, vinyl trichlorosilane, vinyltris(β-methoxyethoxy)silane, 3-methacryloxypropyltrimethoxysilane, 3-acryloxypropyl trimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane, but the present disclosure is not limited thereto.

The metal compound included in the metal-containing resist (e.g., metal-containing photoresist) may include at least one of an organic oxy group-containing tin compound or an organic carbonyloxy group-containing tin compound.

As an example, the metal compound included in the metal-containing resist may be represented by Chemical Formula 2.

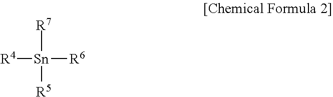

In Chemical Formula 2,
R⁴ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group or a substituted or unsubstituted C6 to C20 aryl group), and
R⁵ to R⁷ may each independently be a halogen, an alkoxo or aryloxo group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR⁷R⁸, wherein R⁷ and R⁸ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR⁹(CO)R¹⁰, wherein R⁹ and R¹⁰ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or an amidinato group (—NR¹¹C(NR¹²)R¹³, wherein R¹¹, R¹², and R¹³ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

For example, the metal compound included in the metal-containing resist may be at least one of an alkyloxy group-containing tin compound or an alkylcarbonyloxy group-containing tin compound.

In one or more embodiments, a method of forming patterns includes the (e.g., act or task) step of removing the edge beads using the aforementioned composition for removing edge beads from the metal-containing resist. For example, the manufactured pattern may be a photoresist pattern, for example, a negative-type or kind photoresist pattern.

A method of forming patterns according to one or more embodiments includes coating a metal-containing resist composition on a substrate, coating the aforementioned composition for removing edge beads from metal-containing resists along an edge of the substrate, drying and heating to form a metal-containing photoresist layer on the substrate, exposing the metal-containing photoresist layer, and developing the metal-containing photoresist layer.

For example, the forming of patterns using the metal-containing resist composition may include coating a metal-containing resist composition on a substrate (on which a thin film is formed) by spin coating, slit coating, inkjet printing, and/or the like, and drying the coated metal-containing resist composition to form a photoresist layer. The metal-containing resist composition may include a tin-based compound, and for example, the tin-based compound may include at least one of an organic oxy group-containing tin compound or an organic carbonyloxy group-containing tin compound.

In an embodiment, the composition for removing edge beads from the metal-containing resists along the edge of the substrate may be coated while rotating the substrate at an appropriate or suitable speed (e.g., 500 rpm or more).

Subsequently, a first heat treatment process of heating the substrate on which the photoresist layer is formed is performed. The first heat treatment process may be performed at a temperature of about 80° C. to about 120° C. and in this process, the solvent is evaporated and the photoresist layer may be more firmly adhered to the substrate.

Then, the photoresist layer is selectively exposed.

For example, examples of light that may be used in the exposure process may include not only light having a short wavelength such as i-line (wavelength 365 nm), KrF excimer laser (wavelength 248 nm), or ArF excimer laser (wavelength 193 nm), but also light having a high energy wavelength such as EUV (Extreme UltraViolet, wavelength 13.5 nm), E-Beam (electron beam), and/or the like.

In some embodiments, the light for exposure may be short-wavelength light having a wavelength range of about 5 nm to about 150 nm, and light having a high energy wavelength such as EUV (Extreme UltraViolet, wavelength 13.5 nm), E-Beam (electron beam), and/or the like.

In the (e.g., act or task) step of forming the photoresist pattern, a negative-type or kind pattern may be formed.

The exposed region of the photoresist layer has a solubility different from that of the unexposed region of the photoresist layer as a polymer is formed by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the photoresist layer becomes difficult to be dissolved in a developer.

For example, the photoresist pattern corresponding to the negative tone image may be completed by dissolving and removing the photoresist layer corresponding to the unexposed region using an organic solvent such as 2-heptanone.

The developer used in the method of forming patterns according to one or more embodiments may be an organic solvent, for example, one or more ketones such as methyl ethyl ketone, acetone, cyclohexanone, and/or 2-haptanone, alcohols such as 4-methyl-2-propanol, 1-butanol, isopropanol, 1-propanol, and/or methanol, esters such as propylene glycol monomethyl ether acetate, ethyl acetate, ethyl lactate, n-butyl acetate, butyrolactone, aromatic compounds such as benzene, xylene, and/or toluene, and/or a (e.g., any suitable) combination thereof.

The photoresist pattern formed by exposure to not only light having a short wavelength such as i-line (wavelength 365 nm), KrF excimer laser (wavelength 248 nm), or ArF excimer laser (wavelength 193 nm), but also light having high energy such as EUV (Extreme UltraViolet, wavelength 13.5 nm) or E-beam (electron beam) may have a thickness width of about 5 nm to about 100 nm. For example, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

Also, the photoresist pattern may have a pitch having a half-pitch of less than or equal to about 50 nm, for example, less than or equal to 40 nm, less than or equal to 30 nm, less than or equal to 20 nm, or less than or equal to 15 nm, and a line width roughness of less than or equal to about 10 nm, for example, less than or equal to about 5 nm, less than or equal to about 3 nm, or less than or equal to about 2 nm.

A method of forming patterns according to one or more embodiments includes coating a metal-containing resist composition on a substrate, removing edge beads of the metal-containing resists, drying and heating to form a metal-containing photoresist layer on the substrate, exposing the metal-containing photoresist layer, and developing the metal-containing photoresist layer using the aforementioned developer composition of metal-containing resists.

The coating of the metal-containing resist composition on a substrate is the same as described above.

The removing of edge beads of the metal-containing resists may be performed by coating an appropriate or suitable amount of a suitable (e.g., generally known) organic solvent or composition for removing edge beads along the edge of the substrate while spinning the substrate at an appropriate or suitable speed (e.g., 500 rpm or more).

The drying and heating to form a metal-containing photoresist layer on the substrate is the same as described above.

The exposing of the metal-containing photoresist layer is the same as described above.

The photoresist pattern corresponding to the negative tone image may be completed by dissolving the photoresist layer corresponding to the unexposed region using the aforementioned developer composition of metal-containing resists and then removing the photoresist layer.

Hereinafter, a method of forming patterns by development is described in more detail with reference to the drawings.

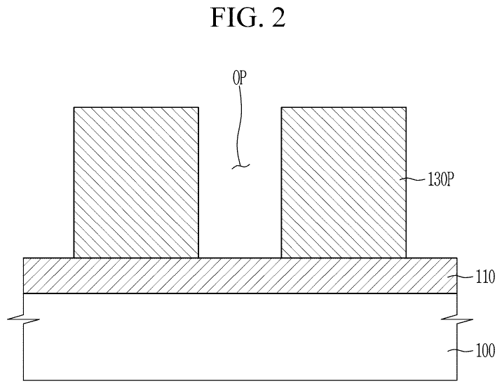

FIGS. 2 to 4 are cross-sectional views schematically illustrating a process sequence in order to explain a method of forming patterns.

Referring to FIG. 2, the exposed photoresist layer is developed to form a photoresist pattern 130P on the substrate 100.

In one or more embodiments, the exposed photoresist layer may be developed to remove an unexposed region of the photoresist layer, and the photoresist pattern 130P including the exposed region of the photoresist layer may be formed. The photoresist pattern 130P may include a plurality of openings OP.

In one or more embodiments, the development of the photoresist layer may be performed through a negative-tone development (NTD) process. Herein, the metal-containing photoresist developer composition according to one or more embodiments may be used as a developer composition.

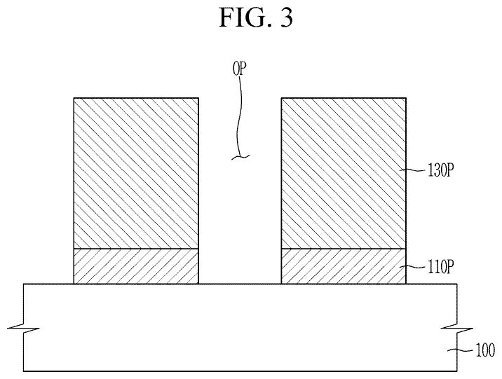

Referring to FIG. 3, the photoresist pattern 130P is used to process a feature layer 110 from the result shown in FIG. 2.

For example, the feature layer 110 is processed through one or more suitable processes of etching the feature layer 110 exposed through the openings OP of the photoresist pattern 130P, injecting impurity ions into the feature layer 110, forming an additional film on the feature layer 110 through the openings OP, deforming (e.g., removing) a portion of the feature layer 110 through the openings OP, and/or the like. FIG. 3 illustrates an example process of processing a feature pattern 110P by etching the feature layer 110 exposed through the openings OP.

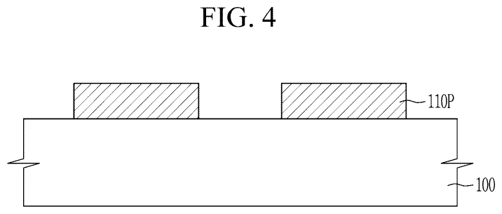

Referring to FIG. 4, the photoresist pattern 130P remaining on the feature pattern 110P is removed from the result shown in FIG. 3. In order to remove the photoresist pattern 130P, an ashing and stripping process may be used.

A method of forming patterns according to one or more embodiments includes coating a metal-containing resist composition on a substrate, coating the aforementioned composition for removing edge beads from metal-containing resists along an edge of the substrate, drying and heating to form a metal-containing photoresist layer on the substrate, exposing the metal-containing photoresist layer, and developing the metal-containing photoresist layer using the aforementioned developer composition of metal-containing resists.

Each (e.g., act or task) step of the method is substantially the same as described above, but in the removing (e.g., act or task) step of edge beads and the developing (e.g., act or task) step, the composition for removing edge beads from metal-containing resists or the developer composition of metal-containing resists according to embodiments of the present disclosure are concurrently (e.g., simultaneously) used to effectively improve an effect of removing the edge beads and solubility of the unexposed region and thus satisfying needs or desires for processing and patterning of smaller features, resultantly realizing excellent or suitable contrast characteristics, excellent or suitable sensitivity, and reduced line edge roughness (LER).

Hereinafter, the present disclosure will be described in more detail through examples relating to the preparation of the aforementioned composition for removing edge beads from metal-containing resists and developer composition of metal-containing resists. However, the technical features of the present disclosure are not limited by the following examples.

Preparation of Composition for Removing Edge Beads from Metal-Containing Resists/Developer Composition

### Example 1

Difluoroacetic acid was mixed with propylene glycol methyl ether acetate (PGMEA) as a solvent in a composition shown in Table 1 and then, dissolved therein by shaking at room temperature (25° C.). Subsequently, the solution was filtered with a PTFE filter with a pore size of 1 μm, thereby obtaining a final composition.

### Examples 2 to 6 and Comparative Examples 1 and 2

Each composition was obtained in substantially the same manner as in Example 1 except that the above composition was respectively changed as shown in Table 1.

TABLE 1

Composition for removing edge beads from metal
containing resist/developer composition

| | Carboxylic acid (wt %) | Solvent (wt %) |
|---|---|---|
| Example 1 | DFAA (0.01) | PGMEA (99.99) |
| Example 2 | DFAA (0.05 | PGMEA (99.95) |
| Example 3 | DFAA (0.1) | PGMEA (99.0) |
| Example 4 | DFPA (0.01) | PGMEA (99.99) |
| Example 5 | DFPA (0.05) | PGMEA (99.95) |
| Example 6 | DFPA (0.1) | PGMEA (99.0) |
| Comparative | AA (0.05) | PGMEA (99.95) |
| Example 1 | | |
| Comparative | Propionic acid (0.05) | PGMEA (99.95) |
| Example 2 | | |

*DFAA: difluoroacetic acid
*DFPA: 2,2-difluoropropionic acid
*AA: acetic acid

### Preparation of Organometal-Containing Photoresist Composition

An organometallic compound having a structure of Chemical Formula C was dissolved in 4-methyl-2-pentanol at a concentration of 1 wt % and then, filtered with a 0.1 μm PTFE syringe filter to prepare a photoresist composition.

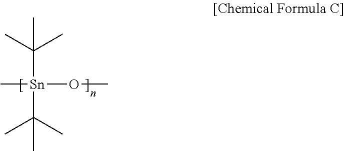

### Evaluation: Evaluation of Contrast Performance and Sensitivity

A metal-containing photoresist (PR) composition was spin-coated on an 8-inch wafer at 1,500 rpm for 30 seconds and then, heat-treated at 160° C. for 60 seconds to manufacture a coated wafer.

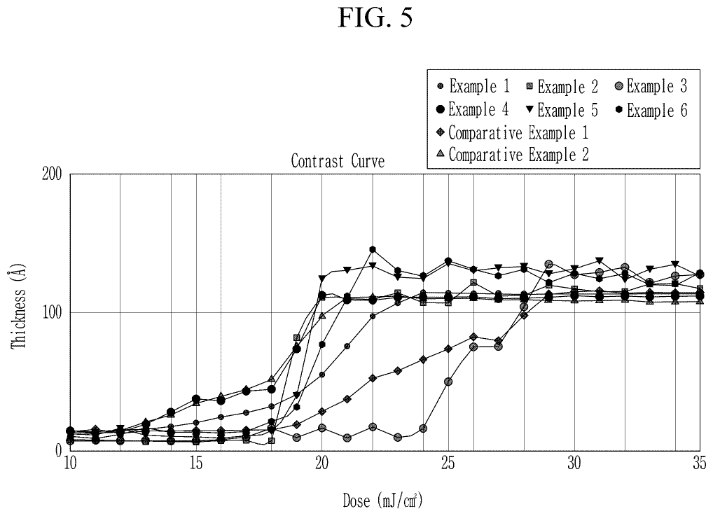

After exposing this coated wafer to a dose of 10 to 100 mJ in a rectangular shaped pattern of 1.2 cm×0.9 cm by using a KrF scanner (PAS 5500/700D, ASML) and heat-treating it at 160° C. for 90 seconds, the developer compositions according to Examples 1 to 6 and Comparative Examples 1 to 2 were respectively applied thereto to develop it and then, finally heat-treated at 240° C. for 60 seconds to obtain patterned wafers. The patterned wafers were respectively measured with respect to a thickness of each exposed region to obtain a contrast curve, which is shown in FIG. 5 and from which contrast performance (γ(contrast)) and sensitivity (D₁₀₀) were calculated, and the results are provided in Table 2.

$$γ ( contrast ) = 1 / log ( {D}_{100} / {D}_{0} )$$

D₁₀₀=Exposure dose at which 100% PR still remains
D₀=Exposure dose at which PR is completely removed

TABLE 2

| | γ (Contrast) | Sensitivity (D₁₀₀) |
|---|---|---|
| Example 1 | 443 | 20 |
| Example 2 | 2409 | 20 |
| Example 3 | 1625 | 29 |
| Example 4 | 443 | 20 |
| Example 5 | 1712 | 20 |
| Example 6 | 1300 | 39 |
| Comparative Example 1 | 463 | 29 |
| Comparative Example 2 | 401 | 21 |

the base of log (D₁₀₀/D₀) is 10.

FIG. 5 is a contrast curve obtained by measuring the thickness of each exposed region on each of the patterned wafers.

Referring to FIG. 5, comparing slopes of the contrast curves, Example 2 turned out to realize much more excellent or suitable resolution.

In addition, results of Table 2 show that if the metal-containing photoresist developer compositions according to the examples were applied, compared with the metal-containing photoresist developer compositions according to the comparative examples, excellent or suitable contrast performance and excellent or suitable sensitivity characteristics were achieved.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinbefore, the certain embodiments of the present disclosure have been described and illustrated, however, it is apparent to a person with ordinary skill in the art that the present disclosure is not limited to these embodiments as described, and may be variously modified and transformed without departing from the spirit and scope of the present disclosure. Descriptions of features or aspects within each embodiment should typically be considered as available for other similar features or aspects in other embodiments. Accordingly, it is to be understood that present disclosure is not limited to the disclosed embodiments, but, on the contrary, is intended to cover various modifications and equivalent arrangements included within the spirit and scope of the appended claims, and equivalents thereof.

Reference Numerals

| | |
|---|---|
| 1: substrate support portion | 2: spray nozzle |
| 10: photoresist solution | 12: edge bead |
| 100: substrate | OP: opening |

What is claimed is:

1. A composition comprising:
a C1 to C10 carboxylic acid compound substituted with at least one fluorine; and
an organic solvent,
wherein the composition is for removing an edge bead from a metal-containing photoresist and/or is a developer composition of the metal-containing photoresist.

2. The composition as claimed in claim 1, wherein
the C1 to C10 carboxylic acid compound substituted with at least one fluorine is represented by Chemical Formula 1: 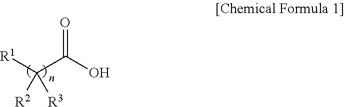
wherein, in Chemical Formula 1,
R¹ to R³ are each independently hydrogen, fluorine, a fluorine-containing group, or a substituted or unsubstituted C1 to C5 alkyl group,
n is one of the integers from 1 to 5, and
at least one of R¹ to R³ is fluorine or the fluorine-containing group.

3. The composition as claimed in claim 2, wherein
at least one of R² or R³ is fluorine or the fluorine-containing group.

4. The composition as claimed in claim 2, wherein
R² and R³ are each independently fluorine or the fluorine-containing group.

5. The composition as claimed in claim 2, wherein
R² and R³ are each independently fluorine.

6. The composition as claimed in claim 1, wherein
the C1 to C10 carboxylic acid compound substituted with at least one fluorine is at least one selected from among difluoroacetic acid, 2,2-difluoropropionic acid, trifluoroacetic acid, and monofluoroacetic acid.

7. The composition as claimed in claim 1, wherein
the composition comprises about 0.01 wt % to about 5 wt % of the C1 to C10 carboxylic acid compound substituted with at least one fluorine, and
about 95 wt % to about 99.99 wt % of the organic solvent.

8. The composition as claimed in claim 1, wherein
the metal-containing photoresist comprises at least one of an organic oxy group-containing tin compound or an organic carbonyloxy group-containing tin compound.

9. The composition as claimed in claim 1, wherein
the metal-containing photoresist comprises a compound represented by Chemical Formula 2: 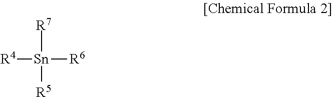
wherein, in Chemical Formula 2,
R⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a}, wherein L^{a} is a substituted or unsubstituted C1 to C20 alkylene group and R^{a} is a substituted or unsubstituted C1 to C20 alkyl group or a substituted or unsubstituted C6 to C20 aryl group, and
R⁵ to R⁷ are each independently a halogen; an alkoxo or aryloxo group represented by —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR⁷R⁸, wherein R⁷ and R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR⁹(CO)R¹⁰, wherein R⁹ and R¹⁰ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or an amidinato group represented by —NR¹¹C(NR¹²)R¹³, wherein R¹¹, R¹², and R¹³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

10. A method of forming patterns, the method comprising:
coating a metal-containing photoresist composition on a substrate;
coating the composition as claimed in claim 1 along an edge of the substrate;
drying and heating to form a metal-containing photoresist layer on the substrate;
exposing the metal-containing photoresist layer to light; and
developing the metal-containing photoresist layer,
wherein the composition is for removing the edge bead from the metal-containing photoresist.

11. A method of forming patterns, the method comprising:
coating a metal-containing photoresist composition on a substrate;
removing metal-containing resist edge beads;
drying and heating to form a metal-containing photoresist layer on the substrate;
exposing the metal-containing photoresist layer to light; and
developing the metal-containing photoresist layer utilizing the composition as claimed in claim 1,
wherein the composition is the developer composition of the metal-containing photoresist.

12. A method of forming patterns, the method comprising:
coating a metal-containing photoresist composition on a substrate;
coating the composition as claimed in claim 1 along an edge of the substrate;
drying and heating to form a metal-containing photoresist layer on the substrate;
exposing the metal-containing photoresist layer to light; and
developing the metal-containing photoresist layer utilizing the composition.

13. A metal-containing photoresist edge bead removing composition comprising the composition as claimed in claim 1.

14. A developer composition for metal-containing photoresist comprising the composition as claimed in claim 1.

15. The method as claimed in claim 10, wherein
the metal-containing photoresist composition comprises at least one of an organic oxy group-containing tin compound or an organic carbonyloxy group-containing tin compound.

16. The method as claimed in claim 10, wherein
the metal-containing photoresist composition comprises a compound represented by Chemical Formula 2: 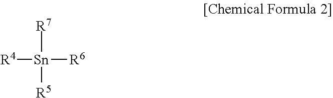
wherein, in Chemical Formula 2,
R⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} wherein L^{a} is a substituted or unsubstituted C1 to C20 alkylene group and R^{a} is a substituted or unsubstituted C1 to C20 alkyl group or a substituted or unsubstituted C6 to C20 aryl group, and
R⁵ to R⁷ are each independently a halogen; an alkoxo or aryloxo group represented by —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR⁷R⁸, wherein R⁷ and R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR⁹(CO)R¹⁰, wherein R⁹ and R¹⁰ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or an amidinato group represented by —NR¹¹C(NR¹²)R¹³, wherein R¹¹, R¹², and R¹³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

17. The method as claimed in claim 11, wherein
the metal-containing photoresist composition comprises at least one of an organic oxy group-containing tin compound or an organic carbonyloxy group-containing tin compound.

18. The method as claimed in claim 11, wherein
the metal-containing photoresist composition comprises a compound represented by Chemical Formula 2: 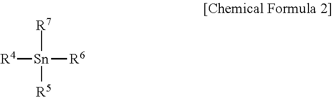
wherein, in Chemical Formula 2,
R⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} wherein L^{a} is a substituted or unsubstituted C1 to C20 alkylene group and R^{a} is a substituted or unsubstituted C1 to C20 alkyl group or a substituted or unsubstituted C6 to C20 aryl group, and
R⁵ to R⁷ are each independently a halogen; an alkoxo or aryloxo group represented by —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR⁷R⁸, wherein R⁷ and R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR⁹(CO)R¹⁰, wherein R⁹ and R¹⁰ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or an amidinato group represented by —NR¹¹C(NR¹²)R¹³, wherein R¹¹, R¹², and R¹³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

19. The method as claimed in claim 12, wherein
the metal-containing photoresist composition comprises at least one of an organic oxy group-containing tin compound or an organic carbonyloxy group-containing tin compound.

20. The method as claimed in claim 12, wherein
the metal-containing photoresist composition comprises a compound represented by Chemical Formula 2: 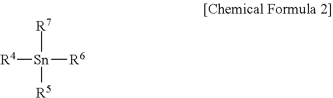
wherein, in Chemical Formula 2,
R⁴ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} wherein L^{a} is a substituted or unsubstituted C1 to C20 alkylene group and R^{a} is a substituted or unsubstituted C1 to C20 alkyl group or a substituted or unsubstituted C6 to C20 aryl group, and
R⁵ to R⁷ are each independently a halogen; an alkoxo or aryloxo group represented by —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R⁶, wherein R⁶ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR⁷R⁸, wherein R⁷ and R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR⁹(CO)R¹⁰, wherein R⁹ and R¹⁰ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or an amidinato group represented by —NR¹¹C(NR¹²)R¹³, wherein R¹¹, R¹², and R¹³ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.
